(19) United States
(12) Patent Application Publication
(10) Pub. No.: US 2025/0065433 A1
(43) Pub. Date: Feb. 27, 2025

(54) ARC STABILITY DETERMINATION BASED ON NOZZLE VOLTAGE

(71) Applicant: The ESAB Group Inc., North Bethesda, MD (US)

(72) Inventor: Erik Anthony Leger, Peterborough, NH (US)

(21) Appl. No.: 18/886,075

(22) Filed: Sep. 16, 2024

Related U.S. Application Data
(63) Continuation of application No. PCT/US2023/015628, filed on Mar. 20, 2023.
(60) Provisional application No. 63/321,838, filed on Mar. 21, 2022.

(51) Int. Cl. B23K 10/00; G01R 19/12

(52) U.S. Cl. CPC B23K 10/00; G01R 19/12

(57) ABSTRACT

A system and method for determining the stability of an arc during a plasma cutting operation based on a measured voltage of a nozzle of a plasma cutting torch is disclosed. The determined arc stability may be correlated with one or more process parameters of a cutting operation in order to determine the ideal values of the one or more process parameters for maximizing cut quality.

### CROSS-REFERENCE TO RELATED APPLICATION

This application is a continuation of International (PCT) Patent Application No. PCT/US2023/015628, filed Mar. 20, 2023, entitled “ARC STABILITY DETERMINATION BASED ON NOZZLE VOLTAGE,” which claims priority to U.S. Provisional Patent Application No. 63/321,838, entitled “ARC STABILITY DETERMINATION BASED ON NOZZLE-ELECTRODE VOLTAGE,” filed Mar. 21, 2022, the entireties of which are incorporated herein by reference for all purposes.

### TECHNICAL FIELD

The present disclosure relates to determining the stability of an arc of a cutting torch based on a voltage between an electrode and a nozzle (also called a tip), as well as providing a quantitative approach for determining real-time cut quality.

### BACKGROUND

Conventional arc plasma torches (e.g., plasma cutting torches) include an electrode surrounded by a tip or nozzle. Typically, a distal end of the electrode and an opposing inner surface of the nozzle at least partially define a plasma chamber. During some start-ups, an arc is sparked between the electrode and the nozzle. Then, a process gas flowing through the plasma chamber (between the nozzle and the electrode) pushes the arc out of an orifice at a distal end of the nozzle and onto a workpiece. Thus, the arc bridges a gap between the electrode and the workpiece and, ideally, extends from an emissive insert (e.g., a hafnium insert) included at a center of the distal face of the electrode to the workpiece. However, during a cut, the arc can sometimes move along the distal face of the electrode (e.g., off the emissive insert) or otherwise become unstable. The stability of the arc corresponds to a quality of a cut or weld. That is, a stable arc (e.g., an arc that is relatively stationary between a distal end of the electrode and workpiece) provides a relatively better cut quality than a cut performed with an unstable arc (e.g., an arc that moves chaotically between a distal end of the electrode and workpiece).

Generally, determining a cut quality is subjective. That is, there is no standardized, quantitative way to measure or determine whether a torch is properly configured and/or if there is a defect in a consumable. Typically, for a particular consumable stack (e.g., electrode, nozzle, and shield), each parameter is set using a trial and error method to generate a stable arc. This method involves changing each of the multiple process parameters until a user finds a configuration which leads to the best cut quality, where the user subjectively determines the cut quality. As these variables are assumed to be fixed during development, generally, they cannot be accounted for during operation in conventional cutting systems.

### SUMMARY

The techniques presented herein provide a method and system for determining arc stability based on a measured voltage of a consumable. In one aspect, a method includes initiating a cutting operation with a torch, measuring a voltage of a nozzle, and determining an arc stability response based on the measured voltage.

In some implementations the method, further includes adjusting one or more process parameters during the cutting operation when the arc stability response does not meet a criteria. The one or more process parameters may include one or more of cut speed, arc momentum, cut height, arc voltage, shield gas pressure, process gas pressure, and cut current. In some instances, the criteria may include a desired instantaneous rate of change of the measured voltage.

In some cases, the measured voltage is measured between the nozzle and an electrode, a ground, and/or another component.

In some implementations, the further includes determining a performance of the torch based on the arc stability response. The performance of the torch may be indicative of a cut quality produced by the torch and/or wear of a consumable used in the torch. In some cases, the method may further include adjusting one or more process parameters until the arc stability response meets a criteria.

In some instances, the arc stability response is indicative of movement of an arc extending between an electrode and a workpiece. The arc stability response may include an instantaneous rate of change value and/or a rolling time average of an absolute value of the instantaneous rate of change of the measured voltage.

In some aspects, the techniques described herein relate to a system, including: a power supply; a torch including an electrode and a nozzle; and a controller configured to monitor a voltage of the nozzle and determine an arc stability response of the torch based on the voltage.

In some implementations, the voltage of the nozzle is measured with respect to the electrode, another component, and/or a ground voltage.

In some cases, the controller is further configured to determine a performance of the torch based on the arc stability response.

In some instances, the controller is further configured to adjust one or more process parameters during a cutting operation when the arc stability response does not meet a criteria. The one or more process parameters may include one or more of cut speed, arc momentum, cut height, arc voltage, shield gas pressure, process gas pressure, and cut current. The criteria may include a desired instantaneous rate of change value of the measured voltage. In some implementations, the controller may be further configured to determine a consumable may be worn or damaged in response to the arc stability response not meeting the criteria after iteratively adjusting the one or more process parameters. Additionally, or alternatively, the controller may be further configured to iteratively adjust the one or more process parameters until the arc stability response meets the criteria.

In some aspects, the arc stability response is indicative of movement of an arc extending between the electrode and a workpiece.

In some implementations, the arc stability response includes an instantaneous rate of change value and/or a rolling time average of an absolute value of the instantaneous rate of change of the measured voltage.

### BRIEF DESCRIPTION OF THE DRAWINGS

To complete the description and in order to provide for a better understanding of the present invention, a set of drawings is provided. The drawings form an integral part of the description and illustrate an embodiment of the present invention, which should not be interpreted as restricting the scope of the invention, but just as an example of how the invention can be carried out. The drawings comprise the following figures:

FIG. 1A is a perspective view of an automated cutting system that may execute the techniques presented herein, according to an example embodiment of the present disclosure.

FIG. 1B is a perspective view of an automated cutting head that may be included in the automated cutting system illustrated in FIG. 1A, according to an example embodiment of the present disclosure.

FIG. 1C illustrates a cross-sectional view of the cutting head of FIG. 1B and a schematic view of a power supply operatively coupled to the cutting head, according to an embodiment.

FIG. 1D illustrates a cross-sectional view of the cutting head of FIG. 1B with an unstable arc.

FIG. 2 illustrates a plurality of graphs depicting a nozzle voltage output over time from the torch head of FIG. 1B.

FIG. 3 depicts a comparison between a graph of a smoothed absolute value of a rate of change of the nozzle voltage over time from FIG. 2 and a corresponding graph of a process gas pressure over time.

FIG. 4A is a block diagram illustrating a method for determining and controlling arc stability for a cutting torch.

FIG. 4B is a block diagram illustrating a method for determining cut quality for a cutting torch.

FIG. 4C is a block diagram illustrating a method for determining an arc stability criteria for a cutting torch.

FIG. 5 is a hardware block diagram of a computing device.

Like reference numerals have been used to identify like elements throughout this disclosure.

### DESCRIPTION OF EXAMPLE EMBODIMENTS

Presented herein are techniques for determining a quality of a cut performed by a cutting torch based on a voltage of a nozzle, also called a tip, of the cutting torch (e.g., a voltage measured between the nozzle and an electrode, a ground, and/or another component). The cutting torch may be a hand-held torch or part of an automated cutting system.

Generally, arc stability impacts a cut quality of a torch. It is hypothesized that the more stable an arc is within a plasma chamber of the torch, the better the cut quality. The stability of the arc of the torch may be determined based on a plurality of mathematical operations and/or transformations on the voltage of the nozzle. For example, the open circuit voltage between the electrode and the nozzle can be used to measure the stability of the arc within a plasma chamber of the torch head. When the arc is stable, the arc is substantially stationary within the plasma chamber, the arc does not substantially move along the electrode, and the voltage between the electrode and nozzle does not substantially fluctuate, if at all. When the arc is not stable, the arc may chaotically move along a face at a distal end of the electrode and within the plasma chamber. The arc movement causes fluctuation in the voltage between the electrode and the nozzle. The fluctuations may be caused by one or more Eddy currents generated within the nozzle by the chaotic movement of the arc. Consequently, the stability of the arc can be determined by monitoring fluctuations, or lack thereof, in the voltage of the nozzle. A periodogram, spectrogram, or smoothed instantaneous rate of change plot of this voltage for example, can be visually and numerically indicative of chaotic or non-chaotic arc behavior, and therefore represents a viable control parameter during development of a model/type of one or more consumables by easily and efficiently tuning one or more process parameters of a cutting operation for use with the model/type of the one or more consumables. Moreover, because arc stability corresponds to cut quality, the voltage measurements provide a quantitative value for cut quality for the torch and the particular model/type of consumables in real-time. Thus, process parameters may be adjusted by an active cut quality controller in real-time based on the voltage measurements.

The arc stability may be affected by a number of process parameters including: condition of the consumables (e.g., wear of the electrode, emissive insert, nozzle, shield etc.), cut speed, arc momentum (e.g., corners, arcs, pierces, etc.), cut height (i.e., between torch tip and workpiece), arc voltage (i.e., voltage between the electrode and the workpiece), shield gas pressure, process gas pressure, cut current, etc. Based on the nozzle voltage measurements, process parameters may be adjusted to optimize the stability of the arc in real-time. That is, process parameters may be varied through a number of values (e.g., via a controller during a cutting operation) until the nozzle voltage fluctuation is minimized, and thus, the stability of the arc is maximized. Maximizing the arc stability may also maximize cut quality. Further, if all parameters have been maximized and the arc is still unstable, a determination may be made by a controller that one or more consumables of the torch head are worn or defective and require replacement.

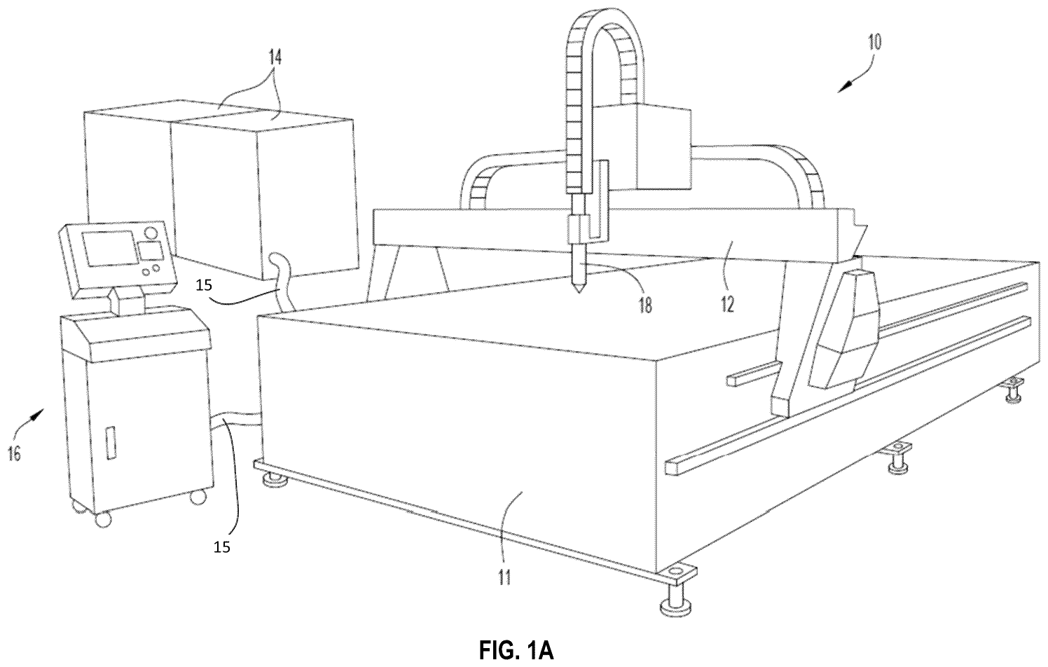

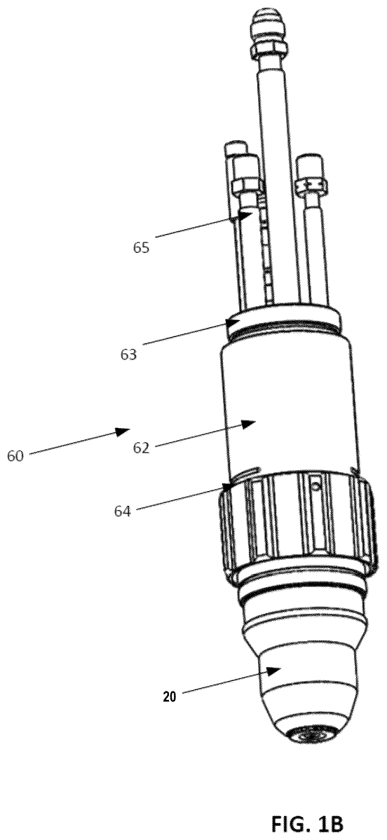

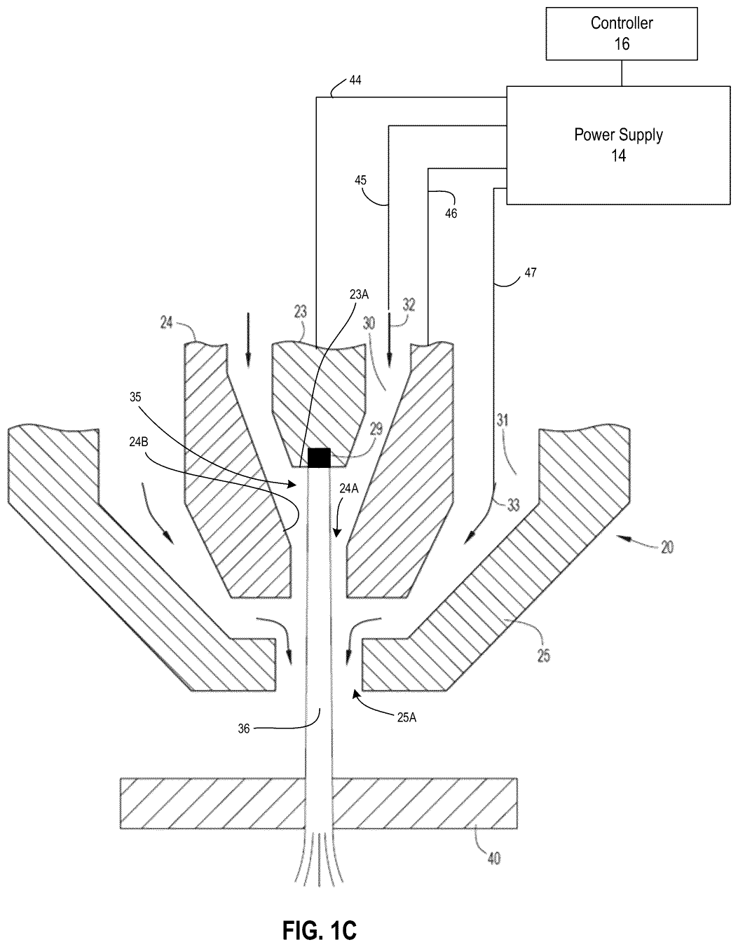

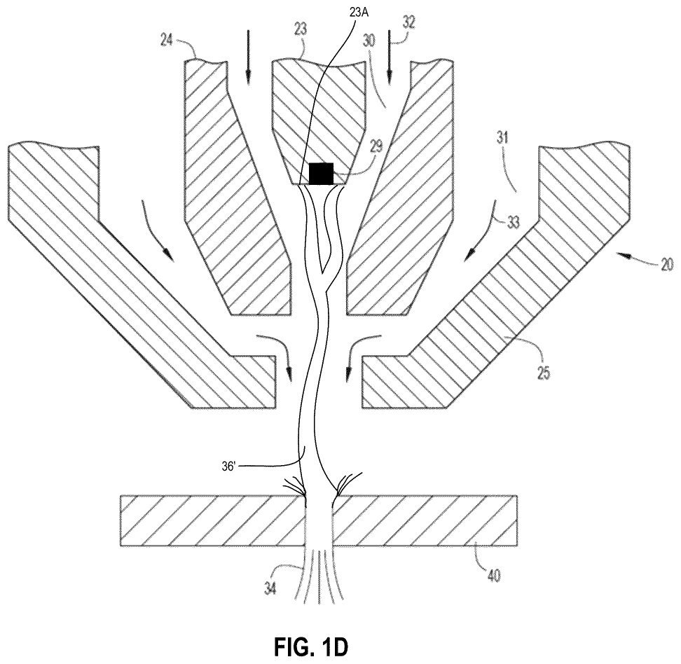

FIG. 1A illustrates an example embodiment of an automated cutting system 10 that may execute the techniques presented herein. However, this automated cutting system 10 is merely presented by way of example and the techniques presented herein may also be executed by manual cutting systems and/or automated cutting systems that differ from the automated cutting system 10 of FIG. 1A (e.g., any robotic or partially robotic cutting system). That is, the cutting system 10 illustrated in FIG. 1A is provided for illustrative purposes.

At a high-level, the cutting system 10 includes a table 11 configured to receive a workpiece (not shown), such as, but not limited to, a sheet of metal. The automated cutting system also includes a positioning system 12 that is mounted to the table 11 and configured to translate or move along the table 11. At least one automated plasma arc torch 18 is mounted to the positioning system 12 and, in some embodiments, multiple automated plasma arc torches 18 may be mounted to the positioning system 12. The positioning system 12 may be configured to move, translate, and/or rotate the torch 18 in any direction (e.g., to provide movement in all degrees of freedom).

Additionally, at least one power supply 14 is operatively connected to the automated plasma arc torch 18 and configured to supply (or at least control the supply of) electrical power and flows of one or more fluids to the automated plasma arc torch 18 for operation. Finally, a controller or control panel 16 is operatively coupled to and in communication with the automated plasma arc torch 18, the one or more power supplies 14, and the positioning system 12. The controller 16 may be configured to control the operations of the automated plasma arc torch 18, one or more power supplies 14, and/or the positioning system 12, either alone or in combination with the one or more power supplies 14.

In at least some embodiments, the one or more power supplies 14 meter one or more flows of fluid (e.g., gas, cooling liquid, water, etc.) received from one or more fluid supplies before, or as, the one or more power supplies 14 supply fluid to the torch 18 via one or more cable conduits. Additionally or alternatively, the automated cutting system 10 may include a separate fluid supply unit (not shown) or units that can provide one or more fluids to the automated torch 18 independent of the one or more power supplies 14. To be clear, as used herein, the term “fluid” shall be construed to include a gas or a liquid. The one or more power supplies 14 may also condition, meter, and supply power to the automated torch 18 via one or more cables 15, which may be integrated with, bundled with, or provided separately from cable conduits for fluid flows. Additional cables 15 for data, signals, and the like may also interconnect the controller 16, the automated plasma arc torch 18, the power supply 14, and/or the positioning system 12. Any cable 15 or cable conduit/hose included in the automated cutting system 10 may be any length. Moreover, each end of any cable 15 or cable conduit/hose may be connected to components of the automated cutting system 10 via any connectors now known or developed hereafter (e.g., via releasable connectors).

FIG. 1B illustrates an example embodiment of an automated cutting head 60 that may be used with an automated cutting system executing the techniques presented herein (e.g., the cutting system 10 of FIG. 1A). As can be seen, the cutting head 60 includes a body 62 that extends from a first end 63 (e.g., a connection end 63) to a second end 64 (e.g., an operating or operative end 64). The connection end 63 of the body 62 may be coupled (in any manner now known or developed hereafter) to an automation support structure (e.g., a cutting table, robot, gantry, etc., such as positioning system 12). Meanwhile, conduits 65 extending from the connection end 63 of the body 62 may be coupled to like conduits in the automation support structure (e.g., positioning system 12) to connect the automated cutting head 60 to a power supply, one or more fluid supplies, a coolant supply, and/or any other components supporting automated cutting operations.

At the other end, the operative end 64 of the body 62 may receive interchangeable components, including consumable components 20 that facilitate cutting operations. For simplicity, FIGS. 1A and 1B do not illustrate connections portions of the body 62 that allow consumable components 20 to connect to the torch body 62 in detail. However, it should be understood that the cutting consumables, such as those schematically illustrated in FIG. 1C, may be coupled to a torch body 62 in any manner. Moreover, to be clear, the consumable stack 20 depicted in FIGS. 1B and 1C (with an external perspective view and a schematic cross-sectional illustration, respectively) is merely representative of a consumable stack that may be used with an automated torch executing the techniques presented herein. Similarly, while none of the Figures of the present application illustrate an interior of torch body 62, it is to be understood that any unillustrated components that are typically included in a torch, such as components that facilitate cutting operations, may (and, in fact, should) be included in a torch executing example embodiments of the present application.

Referring to FIG. 1C, a schematic of the power supply 14 and a cross-sectional view of the consumable stack 20 of the torch cutting head 60 are illustrated. The power supply 14 includes a controller 16. The power supply 14 and controller 16 are electrically coupled to the consumable stack 20 via conductors 44 and 46, and fluidly coupled to the consumable stack 20 via fluid conduits 45 and 47. The controller 16 monitors and controls electrical power and a flow of one or more gases to the consumable stack 20 via the conductors 44, 46 and fluid conduits 45, 47, respectively. The controller 16 may also control movement of the cutting head 60, e.g., when the torch cutting head 60 is part of a robotic cutting system, a CNC cutting system, or similar system. In some implementations, the controller 16 is a component of the cutting system separate from, but electrically coupled to the power supply 14 and torch cutting head 60.

The consumable stack 20 includes an electrode 23 having a distal end 23A, a tip or nozzle 24 having a nozzle orifice 24A, and a shield 25 having a shield orifice 25A. The electrode 23, the nozzle 24, and the shield 25 may be concentric with one another. The electrode 23 and nozzle 24 are electrically coupled to the power supply 14 and the controller 16 via the conductors 44 and 46, respectively. The electrode 23 includes an emissive insert 29 disposed at a center of the distal end 23A. The emissive insert 29 may be made from, but should not be limited to, hafnium and/or titanium. The emissive insert 29 is coaxial with the nozzle orifice 24A and the shield orifice 25A. An arc 36 is depicted discharging from the emissive insert 29 at the distal end 23A through the nozzle orifice 24A and the shield orifice 25A to a workpiece 40.

The consumable stack 20 further includes a first fluid passage 30 fluidly coupled to the fluid conduit 45, a second fluid passage 31 fluidly coupled to the fluid conduit 47, and a plasma chamber 35. The first fluid passage 30 is defined by a radial gap between the electrode 23 and the nozzle 24. The electrode 23 and the nozzle 24 further define the plasma chamber 35 disposed between the distal end 23A and an opposing inner surface 24B of the nozzle 24. The plasma chamber 35 fluidly couples the first fluid passage 30 to the nozzle orifice 24A. The second fluid passage 31 is defined by a radial gap between the nozzle 24 and the shield 25. The electrode 23, nozzle 24, and shield 25 may have any desired shape. In some implementations, the shield 25 may be omitted.

During a cutting operation, an electrical process current is conducted from the power supply 14 to the electrode 23 via conductor 44, a process gas 32 flows through the first fluid passage 30, and a shield gas 33 flows through the second fluid passage 31. The process current sparks an arc between the electrode 23 and nozzle 24 within the plasma chamber 35. The process gas 32 directs the arc 36 out of the plasma chamber 35 through the nozzle orifice 24A and the shield orifice 25A to a workpiece 40. The shield gas 33 surrounds the arc 36 to protect a portion of the workpiece 40 from atmospheric gases during the cutting operation.

In the depicted embodiment, the arc 36 is stable. That is, the arc 36 extends substantially straight from emissive insert 29 at the distal end 23A to the workpiece 40 with substantially no lateral movement with reference to the electrode 23. The stability of the arc 36, and thus a quality of a cut, can be affected by a number of process parameters such as: process/shield gas flow rate and/or pressure, condition of the consumables (e.g., wear of the electrode, nozzle, shield etc.), cut speed, cut/arc momentum (e.g., corners, arcs, pierces, etc.), cut height (i.e., between the torch nozzle 24 and the workpiece 40), arc voltage (i.e., between the electrode 23 and the workpiece 40), cut current, etc. When the process parameters are properly configured, the arc 36 is stable. The stable arc 36 provides a high-quality cut of the workpiece 40.

Conversely, when the arc 36 is unstable, as illustrated in FIG. 1D, that arc 36′ may chaotically move along the distal end 23A of the electrode 23, resulting in a poor cut quality. The instability may be a result of an improper setting of one or more of the above noted process parameters. Moreover, when the arc 36′ discharges from the distal end 23A offset from emissive insert 29, excessive wear of the electrode 23 and/or the nozzle 24 may occur and cause further instability of the arc 36′. Additionally, or alternatively, multiple arcs may be discharged from the electrode 23 and converge at the workpiece 40. Due to the movement of an unstable arc 36′, cut quality is negatively impacted.

Probing or implementing sensors within a plasma chamber of a torch head to determine arc stability is difficult due to the system's sensitivity to fluid flow patterns, heat transfer, and electromagnetic effects. That is, providing sensors within the plasma chamber would negatively impact the operation of the cutting process. This leads to a limited understanding of the interior conditions during a cutting operation, and a limited understanding of the arc stability given the chosen cut process parameters. Moreover, without sensors in the plasma chamber, conventional systems are not dynamic and cannot automatically respond to changes in process parameters. Typically, the performance of the torch head is based on cut quality and cannot be determined until after a cut has been completed.

According to the techniques presented herein, the stability of the arc 36 is determined in real-time using an open circuit voltage between the electrode 23 and the nozzle 24. The nozzle voltage is maintained at a float voltage and is not grounded. Accordingly, the nozzle voltage is sensitive to positional changes in concentricity between the arc 36 and the arc chamber wall (e.g., inner surface 24B of the nozzle 24). For example, the positional changes of the arc 36 may generate Eddy currents within the nozzle 24 that impact the nozzle voltage. The more stable the arc 36, the less fluctuation of the voltage between the electrode 23 and the nozzle 24. The less stable the arc 36 the greater the fluctuation of the voltage between the electrode 23 and the nozzle 24. This voltage can be used as an input variable to produce inference datasets including but not limited to frequency domain representations, periodograms, spectrograms, rolling instantaneous change averages, and linear transformations. These inference datasets derived from the measured voltage of the nozzle 24 (e.g., voltage between the nozzle 24 and the electrode 23, ground, or other component) can be used as real-time feedback to quantitatively determine the stability of the arc 36, and thus, quality of the cut.

The open circuit voltage between the nozzle 24 and the electrode 23 may be monitored via a voltage sensor electrically coupled to the electrode 23 and the nozzle 24. The sensor may be disposed in the torch cutting head 60 or the power supply 14. The sensor may be an oscilloscope, a voltmeter, or other sensing device. In some implementations, the open circuit voltage may be between the nozzle 24 and another component or a ground voltage.

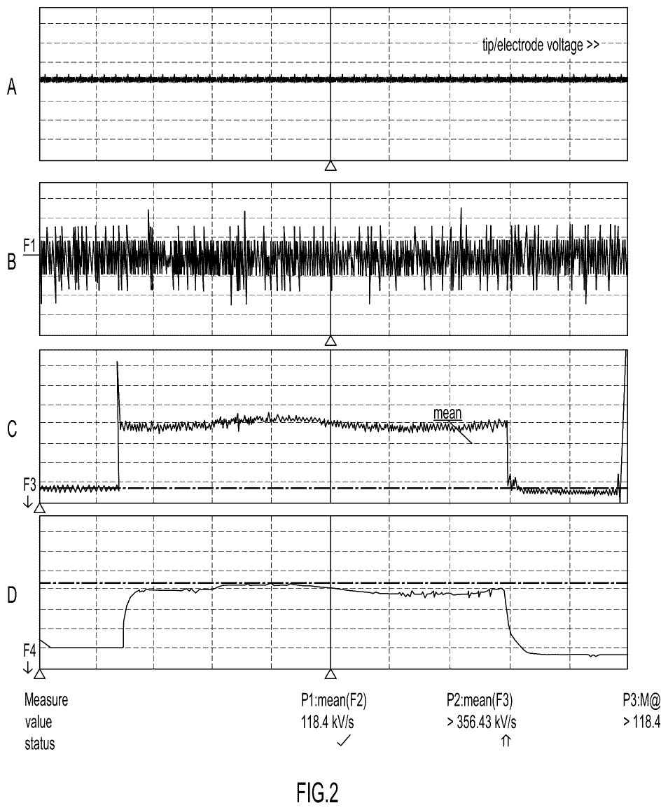

Referring to FIG. 2, a plurality of graphs A-D based on the nozzle-electrode voltage are depicted. Graph A represents a measured voltage between the electrode 23 and the nozzle 24 plotted over time during a cutting operation. Graph B represents a derivative function of the plot in Graph A. That is, Graph B represents the instantaneous rate of change of the nozzle-electrode voltage over time. Graph C represents a rolling time average of an absolute value of the instantaneous rate of change values from Graph B and provides a quantitative value for arc stability. For example, the lower the value in Graph C, the more stable the arc. Conversely, the higher the value along Graph C, the more chaotic the arc. Said another way, the peaks along Graph C represent instances where the arc was moving quickly/chaotically and was less stable over a given window of cut time, while the valleys represent regions where the arc was concentrically stationary with respect to the tip, and thus, was more stable. In some implementations, as represented by Graph D, an additional rolling average of Graph C may be generated to reduce the noise displayed in Graph C. Therefore, by calculating the average of the absolute value of the rate of change of the voltage between the electrode 23 and nozzle 24, the stability of the arc 36 may be determined and optimized in real-time. In some implementations, the voltage of the nozzle may be measured with reference to a ground and/or another component of a cutting system.

By utilizing the proposed methodology, arc stability can be plotted over a varying parameter of choice. The stability of the arc is (in the case of this function) found to be inversely related to this function, allowing the user or controller to sweep through values for process parameters of interest over the course of a cutting operation, and plot the stability response. The process parameters may include one or more of cut speed, arc momentum (e.g., corners, arcs, pierces, etc.), cut height (i.e., between the torch tip and the workpiece), arc voltage (i.e., voltage between the electrode and the workpiece), shield gas pressure, process gas pressure, cut current, etc. Arc stability can be calculated, along with the values for the process parameters, resulting in a simple graphical determination of the ideal value for a process parameter of interest that maximizes cut quality. This can reduce process development time for new consumables by removing guess work and can be iteratively repeated for other process parameters of interest during development of new consumables. Further, the stability response may be provided to a user or controller in real-time feedback during a cutting operation, and the user or controller may adjust one or more parameters based on the stability response (sometimes referred to as stability feedback) to improve cut quality.

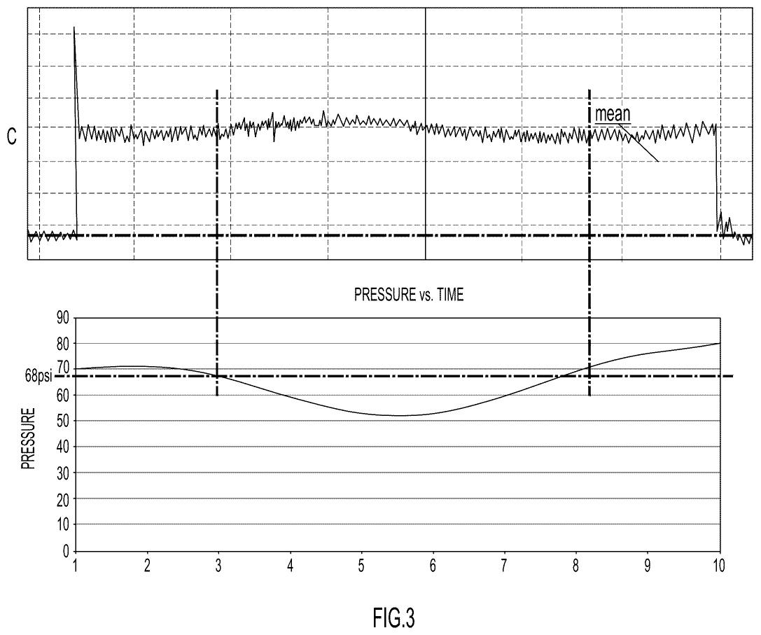

Referring to FIG. 3, an example of the arc stability being plotted over a varying parameter is depicted. As illustrated, Graph C from FIG. 2 is aligned with a plot of a process gas pressure represented in pounds per square inch (psi) over time. As depicted in FIG. 3, as the pressure of the process gas 32 is adjusted between 50 and 80 psi, the rate of change of the nozzle-electrode voltage, and thus the stability of the arc 36, varies. According to the illustrated graphs, the rate of change of the nozzle-electrode voltage is minimized when the process gas 32 reaches about 68 psi. That is, movement of the arc 36 within the plasma chamber 35 and/or along the distal end 23A of the electrode 23 is minimized when the process gas pressure is at approximately 68 psi. Said another way, the arc stability is maximized at 68 psi. Conversely, the rate of change of the arc 36 is maximized around 55 psi. That is, arc movement within the plasma chamber 35 and/or along the distal end 23A of the electrode 23 is maximized at 55 psi, and thus, the arc 36′ is least stable.

The value from Graph C provides real-time, quantitative feedback of the stability of an arc in response to changes in pressure of the process gas 32. This provides a quantitative measurement or threshold for determining cut quality of a particular torch head supplied with a particular process gas pressure. Therefore, a user or a controller can quantitatively determine the cut quality and adjust the process gas pressure in real-time during a cutting operation to maximize the quality of the cut. Consequently, the user or the controller does not have to wait until after a cut has been completed and the cut quality has been analyzed by an expert to adjust the process gas pressure, or another process parameter of interest.

Value settings for each process parameter can be similarly varied for a particular torch head and/or consumable stack to determine, in real-time, each value that further improves the quantitative value corresponding to stability of the arc. That is, each process parameter can be adjusted to optimize arc stability in real-time. Thus, a user and/or a controller can quickly and definitively determine a proper configuration of the process parameters for a particular torch head in real-time (e.g., during a cutting operation) without waiting for completion of a cut or a subjective determination of the quality of the cut by an expert.

Moreover, the real-time or dynamic control of each process parameter based on the stability of the arc may also account for evolving environmental variables, such as consumable degradation (e.g., wear), supply pressure inconsistencies, torch momentum variations, misalignment of consumables within the torch, etc. Based on the measured nozzle voltage, a controller can adjust cut parameters to compensate for variables that impact the stability of the arc. For example, a controller can monitor the arc stability feedback (e.g., absolute value of the rate of change of the nozzle-electrode voltage) and output optimized process parameters (e.g., cut speed, cut/arc momentum (e.g., corners, arcs, pierces, etc.), cut height (i.e., between the torch tip and the workpiece), arc voltage (i.e., voltage between the electrode and the workpiece), shield gas pressure, process gas pressure, cut current, etc.) to maintain the stability of the arc. In some implementations, the controller may optimize one parameter at a time. In other implementations, the controller may optimize multiple parameters simultaneously based on the stability feedback.

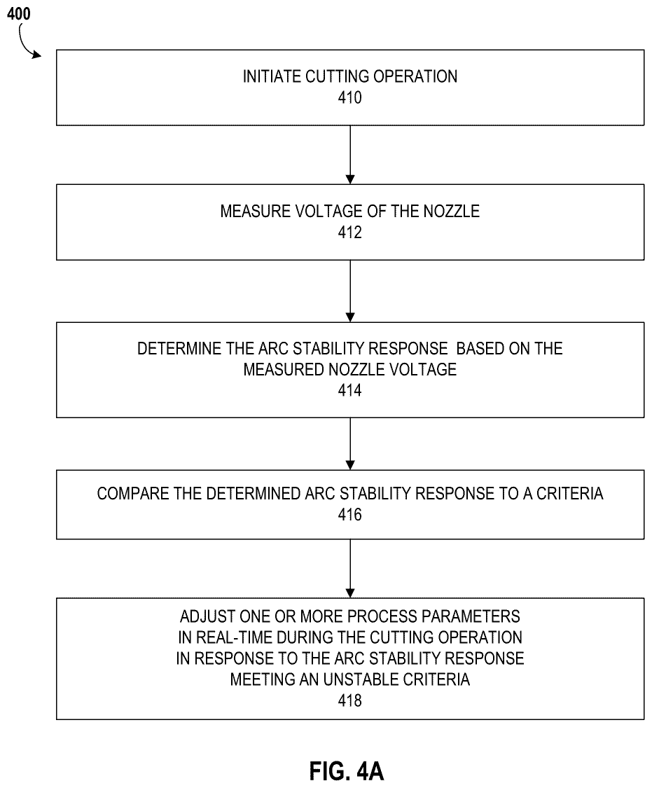

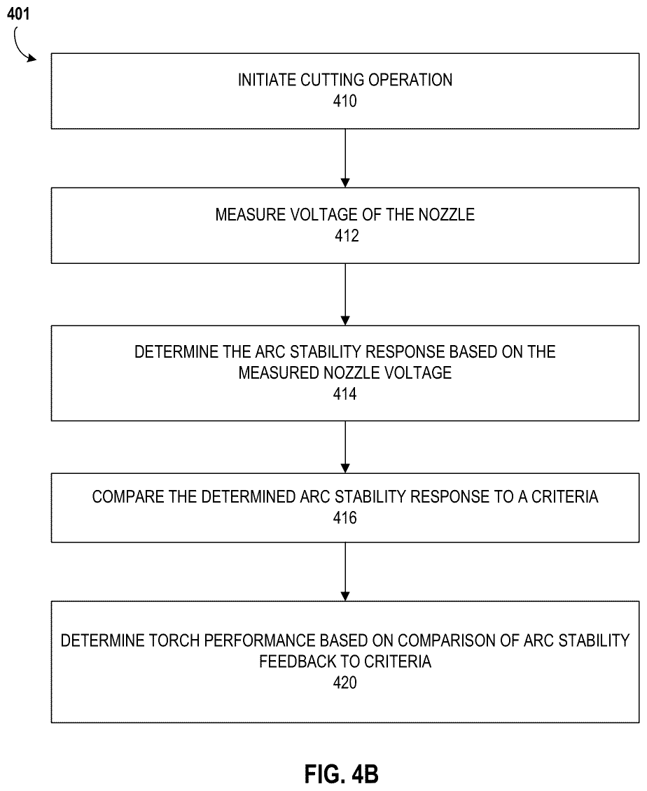

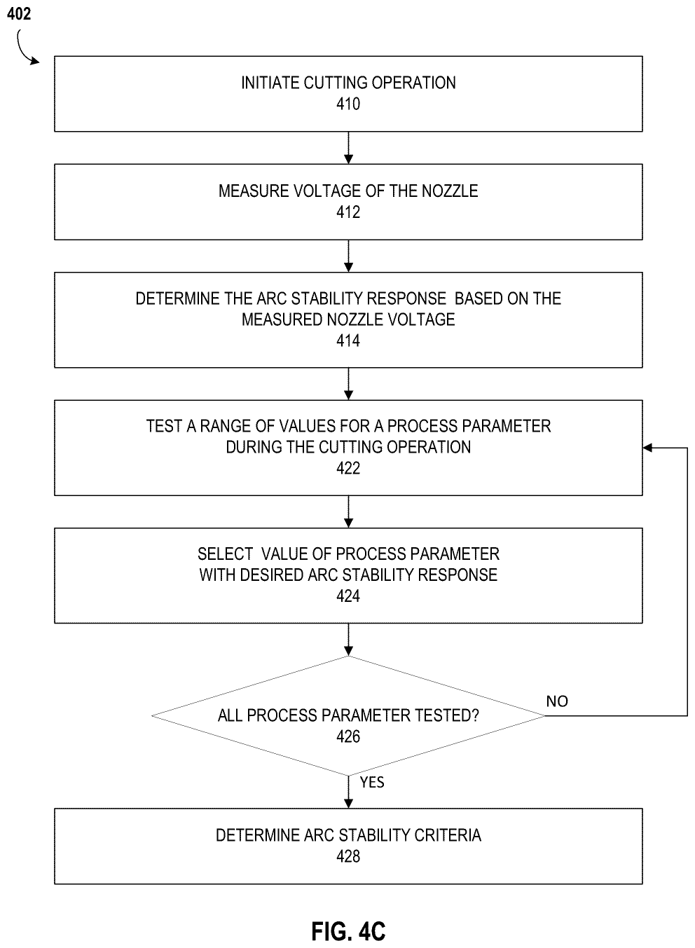

Referring to FIG. 4A, a block diagram of a method 400 for determining arc stability for a particular torch is depicted. The method 400 includes initiating a cutting operation in step 410, measuring a voltage of a nozzle in step 412, determining an arc stability response based on the nozzle voltage in step 414, comparing the determined arc stability response to a predetermined criteria in step 416, and adjusting one or more process parameters in real-time during the cutting operation in response to the arc stability response meeting an unstable criteria (i.e., falling outside of the predetermined criteria or exceeding a predetermined threshold value) in step 418. In some implementations, the voltage of the nozzle is measured between the nozzle and an electrode, another component of the cutting system, and/or a ground voltage.

The arc stability response in step 414 can correspond to a rolling average of the absolute value of the rate of change of the measured nozzle-electrode voltage. It can also correspond to a smoothed time-varied frequency or periodicity spectrum representation of the measured nozzle voltage. Either criteria in step 416 can be a predetermined threshold value for the arc stability r response. For example, with an arc stability response above the threshold value, the arc may be considered unstable (i.e., meeting an unstable criteria). Meanwhile, with an arc stability response below the threshold value, the arc may be considered stable (i.e., meeting a stable criteria). Therefore, the controller may constantly adjust various process parameters until the arc stability response (based on nozzle voltage) is below the predetermined threshold value. In some implementations, the controller may continue to adjust the process parameters until the arc stability response or feedback is minimized. Accordingly, the controller may perform the method 400 to dynamically control one or more process parameters based on the determined stability of the arc during a cutting operation and may also account for evolving environmental variables (e.g., consumable degradation (e.g., wear), supply pressure inconsistencies, torch momentum variations, etc.). For instance, as the consumables wear and/or degrade, the arc may be come less stable. The method 400 may adjust one or more parameters based on the stability feedback to compensate for the wear and/or degradation. In some instances, the controller may adjust the one or more parameter proportionally to a deviation between the arc stability response and the criteria. In some implementations, rather than comparing the arc stability response to a criteria, the arc stability response may be used as feedback to a proportionally adjusts the one or more parameters based on one or more equations. That is, the controller may adjust the one or more parameter proportionally to the arc stability response.

In some implementations, the arc stability response may be used for measuring a quality of cut by a model or type of consumable or determining quality control, especially for the manufacturing of the model/type of consumable parts of the torch over time. For example, a later manufactured consumable may be tested to determine the arc stability response (based on the nozzle voltage transformations), where the determined arc stability response of the later manufactured consumable may be compared to an earlier developed arc stability response of that same consumable model/type. The earlier developed arc stability response may serve as a baseline or desired arc stability response for that particular consumable model/type. A discrepancy between the two values may be attributed to a manufacturing defect in the later manufactured consumable, which allows for the manufacturing defect to be corrected. Thus, manufacturing quality may be quickly and reliably determined by a user or a computer reading the determined stability response without a subjective analysis of cut samples by an expert.

Accordingly, based on the techniques presented herein, the stability of an arc of a cutting torch can be reliably determined based on a measured voltage of a nozzle and thus, provide a quantitative approach for determining cut quality.

Now turning to FIG. 4B, a block diagram of a method 401 for determining a quality of a cut based on the stability response or feedback is depicted. The method 401 includes initiating a cutting operation in step 410, measuring a voltage of a nozzle (e.g., a voltage between the nozzle and an electrode, another component, and/or a ground voltage) in step 412, determining an arc stability response based on the nozzle voltage in step 414, and comparing the determined arc stability response to a predetermined criteria in step 416. These steps may be performed in a manner analogous to steps 410-416 of method 400 in FIG. 4A. The method 401 further includes comparison of the arc stability response to the criteria in step 420. For example, the torch performance may be indicative of a cut quality produced by the torch and/or a condition of one or more torch consumables (e.g., electrode, nozzle, shield, etc.) included in the torch. If the stability response does not meet the criteria, this may be indicative of poor cut quality and/or a poor condition (e.g., excess wear, damage, manufacturing defect, misalignment, etc.) of the one or more torch consumables. In response to determining poor torch performance, the method may further include replacing one or more consumables and/or adjusting the one or more process parameters until the stability response meets the criteria.

To determine the criteria for a stable arc, a model or type of consumable stack may be tested to find values for the one or more process parameters based on the measured nozzle voltage that provide a stable arc. FIG. 4C is a block diagram of a method 402 for determining a criteria for arc stability response for a particular model/type of a consumable stack (e.g., electrode, nozzle, shield, etc.). The method 402 includes initiating a cutting operation with a particular model/type of consumable stack in step 410, measuring a voltage of a nozzle (e.g., voltage between the nozzle and an electrode, another component of the cutting system, and/or a ground) in step 412, and determining an arc stability response based on the nozzle voltage (e.g., instantaneous rate of change of the nozzle voltage, a rolling time average of an absolute value of the instantaneous rate of change of the nozzle voltage, etc.) in step 414. Steps 410-414 may be performed in a manner analogous to steps 410-414 of method 400 in FIG. 4A.

The method 402 further includes testing, or sweeping through, a range of values for a process parameter of the one or more process parameters during the cutting operation in step 422, and selecting a value (from the range of values of the process parameter) that corresponds to a desired arc stability response in step 424. For example, the selected value for the particular process parameter may correspond to the desired arc stability response that is a minimum value of the arc stability response. In step 426, the method 402 further includes determining whether all of the one or more parameter of the cutting operation have been tested. If all of the one or more parameters have not been tested, the method 402 returns to step 422, and each value of the one or more parameters are iteratively adjusted until the desired arc stability response is met. That is, each process parameter is adjusted until the arc stability response is minimized. When all of the one or more parameters of the cutting operation have been tested in step 426, the method 402 moves on to step 428 where the arc stability criteria is determined based on the desired arc stability response(s).

In step 422, the one or more process parameters may include one or more of cut speed, arc momentum (e.g., during corners, arcs, pierces, etc.), cut height (i.e., between the torch tip and the workpiece), arc voltage (i.e., voltage between the electrode and the workpiece), shield gas pressure, process gas pressure, cut current, etc. In step 424, each selected value of each tested process parameter and a corresponding arc stability response for a particular model/type of consumable may be stored in a table and/or database.

In step 428, the determined arc stability criteria corresponds to a minimum value of the arc stability response for a particular type/model of consumable stack with the process parameters set at the selected values. The determined arc stability criteria may be compared to arc stability responses in subsequent cuts by the particular type/model of consumable stack in methods 400 and 401 above. That is, the selected values for the one or more process parameters may be used as reference values and the determined arc stability response may be used as a criteria for evaluating arc stability of a subsequent processing operation. Said yet another way, one or more process parameters and an arc stability response of a subsequent cut may be measured and compared to the reference values stored in the database. In some instances, the arc stability criteria may be just to the minimum arc stability response achieved in steps 422-428. In some implementations, the database may be stored in a non-transitory memory coupled to or integrated with a controller and/or a processor connected to the cutting system.

According to the techniques provided herein, ideal process parameters for a particular model/type of consumable to generate a stable arc during a cutting operation may be efficiently and reliably determined. Moreover, a determined arc response may be used as a criteria to adjust one or more process parameters in real-time to maintain arc stability during subsequent cutting operations with a particular model/type of consumable.

Moreover, monitoring the nozzle voltage (e.g., the voltage between the nozzle and the electrode, ground, or other component) may provide insights into additional characteristics of the arc process, such as arc concentricity, arc restrictivity, arc stiffness, arc isotropy, and external or material homogeny. Arc concentricity corresponds to how centered the arc is within an orifice (e.g., nozzle orifice 24A) of a nozzle (e.g., nozzle 24) during a cutting stage of a cutting operation. Arc concentricity relates to how much the arc is pulled or dragged from an optimal center position due to the torch's motion along a workpiece. Arc concentricity may be calculated while a torch is moving along a workpiece during the cutting stage of the cutting operation based on the instantaneous cut speed multiplied by a rolling average of the nozzle voltage. Based on this calculation, a controller may determine how centered the arc is with respect to the nozzle orifice, and adjust one or more process parameters accordingly. For example, the higher the calculated value for arc concentricity, the greater the arc is pulled out of the center position. Meanwhile, the lower the calculated value, the more centered the arc is within the nozzle. Based on this feedback, a controller may adjust a cut speed to improve arc concentricity.

Additionally, or alternatively, the controller may use the concentricity to distinguish a bushy or non-constrained arc from a constrained arc that is pulled from center due to cut speed. For example, if the concentricity value is high and remains high as the cut speed changes, the arc may be bushy (e.g., have a large diameter), and the process parameters and/or consumable may be changed to correct it. Alternatively, if the concentricity value is minimal but begins to increase above a threshold cut speed, the arc may be pulled out of center by movement of the torch along the workpiece. That is, the arc is otherwise stable and centered within the nozzle orifice and the cut speed is pulling the arc out of alignment. In response, the cut speed may be lowered to improve the concentricity. Consequently, wear of the consumable may be reduced and/or cut quality may be improved.

Arc restrictivity relates to how squeezed or restrained the arc is in the nozzle orifice when the torch is moving slowly along a workpiece. The arc restrictivity may be calculated based on a rolling average of the nozzle voltage divided by the instantaneous cut speed. The calculated value for arc restrictivity corresponds to how much space in the given nozzle orifice the arc occupies. That is, arc restrictivity provides a quantifiable value of the proportion of the nozzle orifice the arc is occupying as compared to the non-ionized process gas flowing between the arc and the nozzle orifice. For example, the lower the arc restrictivity value, the less space the arc is occupying within the nozzle orifice (i.e., the arc is restrained). Conversely, the higher arc restrictivity value, the more space the arc is occupying within the nozzle orifice (i.e., the arc is bushy). The bushy arc may be due to one or more of a worn consumable component and/or a lack of sufficient non-ionized gas flow/pressure through the orifice nozzle. Accordingly, a controller may determine one or more components are worn and/or a flow gas supplied to the plasma chamber should be increased. Moreover, the arc restrictivity value may be used to in determining arc momentum and heat transfer/nozzle orifice cooling. That is, the value may be fed back to a controller for adjusting one or more process parameters (e.g., cut speed, gas process pressure, etc.) to improve the restrictivity value during the cutting operation.

Arc stiffness relates to the resistance to loss of concentricity. That is, arc stiffness is the change in arc trajectory in response to a given a drag force (e.g., force applied to the torch when moving across the workpiece) and/or cut speed. Said yet another way, arc stiffness corresponds to the impulse or force in one direction to move the arc. Bushy or unrestrained arcs may be easier to move than constrained arcs. That is, constrained arcs have greater stiffness than bushy arcs. Arc stiffness may be calculated based on the total average of the instantaneous cut speed multiplied by the rolling average of the nozzle voltage. Taking the standard deviation of the total average results in the arc stiffness value. The lower the stiffness value, the stiffer the arc and more force is required to move it. The higher the stiffness value, the less stiff the arc (e.g., unconstrained or bushy arc) and less force is required to move it. Generally, stiff arcs are preferred to unconstrained arcs. This calculation is useful during higher speed cutting. The stiffness value may be used to determine an upper limit to a cutting speed before arc lag (e.g., difference between speed of the arc traveling through a top of the workpiece vs. the speed of the arc traveling through the bottom of the workpiece) occurs.

Arc isotropy refers to directional tendencies of the arc due to swirl, uneven wear, or manufacturing defects. That is, the arc isotropy value quantifies how isotropic, or evenly resistant to movement, the arc is given a pull force in any direction. The arc isotropy value may provide a particular direction in which the arc may be easily pulled out of concentricity as compared to other directions. The arc isotropy value may be calculated based on a standard deviation of the arc concentricity value (discussed above) for each direction in which the torch moves (e.g. within X, Y coordinates). For example, the isotropy value be calculated for movement in the +X direction, −X direction, +Y direction, and −Y direction. The direction in which the torch is moving may be determined by a controller of an automated cutting system. If the standard deviation of the concentricity in a particular direction (e.g., arc isotropy value) is higher than the isotropy values in two or more other directions, one or more consumables may be unevenly worn in the particular direction. Based on the arc isotropy, the controller may indicate the direction in which the one or more consumables are worn with respect to the torch and recommend adjusting a position of the one or more consumables. Consequently, the one or more consumables may be rotated within the torch to avoid uneven wear and/or replace the one or more consumables.

External or material homogeny relates to the effect the material composition of the workpiece has on the arc. This feedback distinguishes arc instability due to the material composition of the workpiece from an arc instability due to an issue with the torch. For example, a defect or an anomaly in the workpiece (e.g., improper or nonuniform crystalline structure, improper or nonuniform grain size, an impurity, a cavity, etc.) may cause the arc voltage (e.g., electrode to workpiece voltage) and/or the stability of the arc between the nozzle and workpiece to fluctuate. The material homogeny value is calculated by dividing the arc stability, as calculated above, by the stability of the arc voltage. The stability of the arc voltage is calculated by taking a rolling average of the absolute value of the instantaneous rate of change of the electrode to workpiece voltage. By comparing the arc stability with the stability of the arc voltage, a controller may distinguish an issue with the material homogeny from an issue with the torch and/or consumables. That is, if the material homogeny value is low (e.g., below 1), the imperfections in the workpiece may be causing the arc voltage fluctuations. Based on this determination, a controller may adjust the electrode to workpiece distance to reduce the arc voltage fluctuations.

While the above description of the arc characteristics correlate high or low values with an indication of the arc characteristic, the value calculations may be adjusted such that a high or low value correlates with either a positive indication or a negative indication. That is, the calculations described above for the various arc characteristics may be altered such that particular values are set to correspond to desired indications.

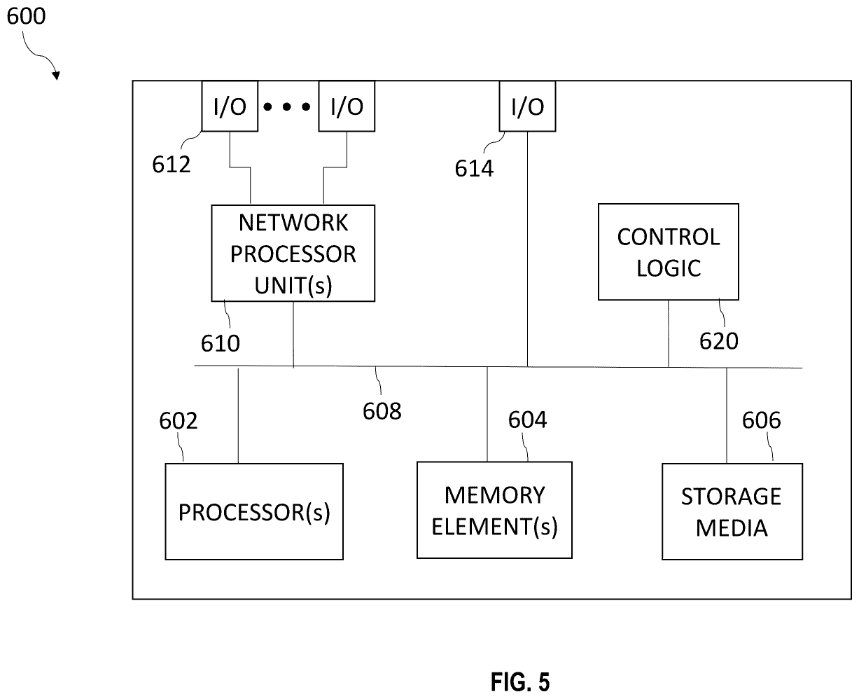

Now referring to FIG. 5, a hardware block diagram of a computing device 600 is illustrated. The illustrated computing device 600 may be an example of a controller as described above. The computing device 600 may perform functions associated with the operations discussed herein in connection with the techniques described herein with reference to FIGS. 1A-1D, 2, 3, and 4A-4C. The computing device 600 may be incorporated in any of the arc process system devices discussed herein, and may be configured to perform the operations discussed herein for determining stability of an arc 36, 36′ and controlling one or more parameters of the arc process operation based on the detected torch arc stability. Thus, any of the controller 16, the automated plasma arc torch 18, the power supply 14, and/or the positioning system 12 of an automated cutting system 10 may execute the techniques presented herein, alone or in combination with one or more other systems/components.

In at least one embodiment, the computing device 600 may be any apparatus that may include one or more processor(s) 602, one or more memory element(s) 604, storage media 606, a bus 608, one or more network processor unit(s) 610 interconnected with one or more network input/output (I/O) interface(s) 612, one or more I/O interface(s) 614, and control logic 620. In various embodiments, instructions associated with logic for the computing device 600 can overlap in any manner and are not limited to the specific allocation of instructions and/or operations described herein.

In at least one embodiment, the processor(s) 602 is/are at least one hardware processor configured to execute various tasks, operations and/or functions for the computing device 600 as described herein according to software and/or instructions configured for the computing device 600. The processor(s) 602 can execute any type of instructions associated with data to achieve the operations detailed herein. In one example, the processor(s) 602 can transform an element or an article (e.g., data, information) from one state or thing to another state or thing. Any of potential processing elements, microprocessors, digital signal processor, baseband signal processor, modem, PHY, controllers, systems, managers, logic, and/or machines described herein can be construed as being encompassed within the broad term “processor”.

In at least one embodiment, the memory element(s) 604 and/or the storage media 606 is/are configured to store data, information, software, and/or instructions associated with the computing device 600, and/or logic configured for the memory element(s) 604 and/or the storage media 606. For example, any logic described herein (e.g., the control logic 620) can, in various embodiments, be stored for the computing device 600 using any combination of the memory element(s) 604 and/or the storage media 606. Note that in some embodiments, the storage media 606 can be consolidated with memory element(s) 604 (or vice versa), or can overlap/exist in any other suitable manner.

In various embodiments, any entity, apparatus, or device as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad terms “memory element” and “storage media.” Data/information being tracked and/or sent to one or more entities, apparatuses, or devices as discussed herein could be provided in any database, table, register, list, cache, storage, and/or storage structure: all of which can be referenced at any suitable timeframe. Any such storage options may also be included within the broad terms “memory element” and “storage media” as used herein.

Note that in certain example implementations, operations as set forth herein may be implemented by logic (as described herein; e.g., the control logic 620) encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by the one or more processor(s) 602, and/or other similar machine(s), etc. Generally, this includes the memory element(s) 604 and/or the storage media 606 being able to store data, software, code, instructions (e.g., processor instructions), logic (e.g., the control logic 620), parameters, combinations thereof, or the like that are executed to carry out operations in accordance with teachings of the present disclosure.

To the extent that embodiments presented herein relate to the storage of data, the embodiments may employ any number of any conventional or other databases, data stores or storage structures (e.g., files, databases, data structures, data or other repositories, etc.) to store information.

In at least one embodiment, the bus 608 can be configured as an interface that enables one or more elements of the computing device 600 to communicate in order to exchange information and/or data. The bus 608 can be implemented with any architecture designed for passing control, data and/or information between the processor(s) 602, the memory elements 604, the storage media 606, peripheral devices, and/or any other hardware and/or software components that may be configured for the computing device 600. In at least one embodiment, the bus 608 may be implemented as a fast kernel-hosted interconnect, potentially using shared memory between processes (e.g., logic), which can enable efficient communication paths between the processes.

In various embodiments, the network processor unit(s) 610 may enable communication between the computing device 600 and other systems, entities, devices, etc., via the network I/O interface(s) 612 (wired and/or wireless) to facilitate operations discussed for various embodiments described herein. In various embodiments, the network processor unit(s) 610 can be configured as a combination of hardware and/or software, such as one or more Ethernet driver(s) and/or controller(s) or interface cards, Fibre Channel (e.g., optical) driver(s) and/or controller(s), wireless receivers/transmitters/transceivers, baseband processor(s)/modem(s), and/or other similar network interface driver(s) and/or controller(s) now known or hereafter developed to enable communications between the computing device 600 and other arc process system devices, arc process system auxiliary components, etc. to facilitate the operations described herein. In various embodiments, the network I/O interface(s) 612 can be configured as one or more Ethernet port(s), Fibre Channel ports, any other I/O port(s), and/or antenna(s)/antenna array(s) now known or hereafter developed. Thus, the network processor unit(s) 610 and/or the network I/O interface(s) 612 may include suitable interfaces for receiving, transmitting, and/or otherwise communicating data and/or information in a network environment.

The I/O interface(s) 614 allow for input and output of data and/or information with other entities that may be connected to the computer device 600. For example, the I/O interface(s) 614 may provide a connection to arc process system devices and/or components. In some implementations, the I/O interface(s) 614 may provide a connection to external devices such as a keyboard, keypad, a touch screen, and/or any other suitable input and/or output device now known or hereafter developed. In some instances, external devices can also include portable computer readable (non-transitory) storage media such as database systems, thumb drives, portable optical or magnetic disks, and memory cards. In still some instances, external devices can be a mechanism to display data to a user, such as, for example, a computer monitor, a display screen, or the like.

In various embodiments, the control logic 620 can include instructions that, when executed, cause the processor(s) 602 to perform operations, which can include, but are not limited to: determining stability of the arc; changing various parameters of the arc process operation; providing overall control operations of the arc process system; interacting with other entities, devices, components, systems, etc. described herein; maintaining and/or interacting with stored data, information, parameters, etc. (e.g., the memory element(s) 604, the storage media 606, data structures, databases, tables, etc.); and/or combinations thereof to facilitate various operations for embodiments described herein.

The programs described herein (e.g., the control logic 620) may be identified based upon application(s) for which they are implemented in a specific embodiment. However, it should be appreciated that any particular program nomenclature herein is used merely for convenience; thus, embodiments herein should not be limited to use(s) solely described in any specific application(s) identified and/or implied by such nomenclature.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

Note that in this Specification, references to various features (e.g., elements, structures, nodes, modules, components, engines, logic, steps, operations, functions, characteristics, etc.) included in “one embodiment”, “example embodiment”, “an embodiment”, “another embodiment”, “certain embodiments”, “some embodiments”, “various embodiments”, “other embodiments”, “alternative embodiment”, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

While the invention has been illustrated and described in detail and with reference to specific embodiments thereof, it is nevertheless not intended to be limited to the details shown, since it will be apparent that various modifications and structural changes may be made therein without departing from the scope of the inventions and within the scope and range of equivalents of the claims. In addition, various features from one of the embodiments may be incorporated into another of the embodiments. Accordingly, it is appropriate that the appended claims be construed broadly and in a manner consistent with the scope of the disclosure as set forth in the following claims.

Reference may be made to the spatial relationships between various components and to the spatial orientation of various aspects of components as depicted in the attached drawings. However, as will be recognized by those skilled in the art after a complete reading of the present disclosure, the devices, components, members, apparatuses, etc. described herein may be positioned in any desired orientation. Thus, the use of terms such as “above,” “below,” “upper,” “lower,” “top,” “bottom,” “left,” “right,” “front,” “rear,” “side,” “height,” “length,” “width,” “interior,” “exterior,” “inner,” “outer,” or other similar terms merely describe points of reference and do not limit the present invention to any particular orientation or configuration. When used to describe a range of dimensions and/or other characteristics (e.g., time, pressure, temperature, distance, etc.) of an element, operations, conditions, etc. the phrase “between X and Y” represents a range that Includes X and Y.

Further, the term “exemplary” is used herein to describe an example or illustration. Any embodiment described herein as exemplary is not to be construed as a preferred or advantageous embodiment, but rather as one example or illustration of a possible embodiment.

Further, the present disclosure may repeat reference numerals and/or letters in the various examples. This repetition is for the purpose of simplicity and clarity, and does not in itself dictate a relationship between the various embodiments and/or configurations discussed.

When used herein, the term “comprises” and its derivations (such as “comprising”, “including,” “containing,” etc.) should not be understood in an excluding sense, that is, these terms should not be interpreted as excluding the possibility that what is described and defined may include further elements, steps, etc. Meanwhile, when used herein, the term “approximately” and terms of its family (such as “approximate,” etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the similar terms, such as, but not limited to, “about,” “around,” and “substantially.”

As used herein, unless expressly stated to the contrary, use of the phrase “at least one of”, “one or more of”, “and/or”, and variations thereof are open-ended expressions that are both conjunctive and disjunctive in operation for any and all possible combination of the associated listed items. For example, each of the expressions “at least one of X, Y and Z,” “at least one of X, Y or Z,” “one or more of X, Y and Z,” “one or more of X, Y or Z,” and “X, Y and/or Z” can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z. Further as referred to herein, “at least one of” and “one or more of” can be represented using the “(s)” nomenclature (e.g., one or more element(s)).

Additionally, unless expressly stated to the contrary, the terms “first,” “second,” “third,” etc. are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, “first X” and “second X” are intended to designate two “X” elements that are not necessarily limited by any order, rank, importance, temporal sequence, or hierarchy of the two elements.

What is claimed is:

1. A method comprising:
initiating a cutting operation with a torch;
monitoring a voltage of a nozzle over a period of time during the cutting operation; and
determining an arc stability response based on a rolling time average of a rate of change of the voltage over the period of time.

2. The method of claim 1, further comprising adjusting one or more process parameters during the cutting operation in response to determining the arc stability response does not meet a criteria.

3. The method of claim 2, wherein the one or more process parameters comprise one or more of cut speed, arc momentum, cut height, arc voltage, shield gas pressure, process gas pressure, or cut current.

4. The method of claim 2, wherein adjusting the one or more process parameters during the cutting operation comprises sweeping the one or more process parameters through a range of values during an additional period of time of the cutting operation, and the method further comprises:
determining a respective arc stability response provided by each value of the range of values of the one or more process parameters; and
selecting a value of the one or more process parameters based on the respective arc stability response provided by the value.

5. The method of claim 4, wherein the value of the one or more process parameters is selected in response to the respective arc stability response meeting the criteria.

6. The method of claim 1, wherein the period of time occurs after initiation of the cutting operation.

7. The method of claim 1, wherein the arc stability response is indicative of a change in cut quality over the period of time.

8. The method of claim 1, wherein monitoring the voltage comprises:
determining a plurality of voltage values over the period of time;
determining an absolute value of an instantaneous change in adjacent voltage values of the plurality of voltage values; and
determining the rolling time average of the rate of change of the voltage over the period of time by determining the rolling time average of the absolute value of the instantaneous change in adjacent voltage values of the plurality of voltage values.

9. The method of claim 1, wherein the arc stability response is indicative of movement of an arc extending between an electrode of the torch and a workpiece during the cutting operation.

10. A system, comprising:
a power supply;
a torch comprising a nozzle; and
a controller configured to:
monitor a voltage of the nozzle over a period of time during a cutting operation of the torch; and
determine an arc stability response of the torch based on a rolling time average of a rate of change of the voltage over the period of time.

11. The system of claim 10, wherein the rolling time average of the rate of change of the voltage is the rolling time average of an absolute value of an instantaneous rate of change of the voltage.

12. The system of claim 10, wherein the controller is configured to adjust a parameter of the torch to change the arc stability response prior to completion of the cutting operation.

13. The system of claim 12, wherein the controller is configured to iteratively adjust the parameter and determine the arc stability response after adjusting the parameter until the arc stability response meets a criteria.

14. The system of claim 12, wherein the parameter comprises a position of the torch with respect to a workpiece.

15. A non-transitory computer readable medium comprising instructions that, when executed by one or more processors, cause the one or more processors to:
monitor a voltage of a nozzle of a torch over a period of time during a cutting operation of the torch;
determine a rolling time average of a rate of change of the voltage over the period of time; and
adjust a parameter of the torch based on the rolling time average of the rate of change of the voltage over the period of time.

16. The non-transitory computer readable medium of claim 15, wherein the instructions, when executed by the one or more processors, cause the one or more processors to adjust the parameter of the torch in response to determining the rolling time average of the rate of change of the voltage over the period of time exceeds a threshold.

17. The non-transitory computer readable medium of claim 15, wherein the instructions, when executed by the one or more processors, cause the one or more processors to monitor the voltage of the nozzle of the torch over an additional period of time during the cutting operation after adjusting the parameter of the torch.

18. The non-transitory computer readable medium of claim 17, wherein the instructions, when executed by the one or more processors, cause the one or more processors to adjust the parameter based on the rolling time average of the rate of change of the voltage over the additional period of time.

19. The non-transitory computer readable medium of claim 17, wherein the instructions, when executed by the one or more processors, cause the one or more processors to adjust an additional parameter in response to determining the rolling time average of the rate of change of the voltage over the additional period of time exceeds a threshold after adjusting the parameter of the torch.

20. The non-transitory computer readable medium of claim 15, wherein the instructions, when executed by the one or more processors, cause the one or more processors to avoid adjusting the parameter of the torch in response to determining the rolling time average of the rate of change of the voltage over the period of time is below a threshold.
